(19) United States
(12) Patent Application Publication
(10) Pub. No.: US 2024/0405117 A1
(43) Pub. Date: Dec. 5, 2024

(54) NITRIDE SEMICONDUCTOR DEVICE

(71) Applicant: ROHM CO., LTD., Kyoto-shi (JP)

(72) Inventor: Hirotaka OTAKE, Kyoto-shi (JP)

(73) Assignee: ROHM CO., LTD., Kyoto-shi (JP)

(21) Appl. No.: 18/798,932

(22) Filed: Aug. 9, 2024

Related U.S. Application Data
(63) Continuation of application No. PCT/JP2022/046702, filed on Dec. 19, 2022.

(30) Foreign Application Priority Data
Feb. 17, 2022 (JP) 2022-022919

(51) Int. Cl. H01L 29/778; H01L 29/20; H01L 29/40; H01L 29/417; H01L 29/423

(52) U.S. Cl. CPC H01L 29/7786; H01L 29/2003; H01L 29/402; H01L 29/41766; H01L 29/42316

(57) ABSTRACT

A nitride semiconductor device includes an electron transit layer, an electron supply layer, a gate layer containing acceptor impurities, a gate electrode, a passivation layer, a source electrode, a drain electrode, and a field plate electrode. The field plate electrode is located on the passivation layer between the gate layer and the drain electrode. The gate layer includes a ridge where the gate electrode is located, a source-side extension extending from the ridge, and a drain-side extension extending from the ridge to a side opposite to the source-side extension. The passivation layer includes a field plate non-overlapping region that does not overlap the field plate electrode and is located immediately above the drain-side extension.

### CROSS-REFERENCE TO RELATED APPLICATIONS

This is a continuation application of PCT Application No. PCT/JP2022/046702, filed on Dec. 19, 2022, which claims priority to Japanese Patent Application No. 2022-022919, filed on Feb. 17, 2022, the entire contents of each of which are incorporated herein by reference.

### BACKGROUND

### 1. Field

This disclosure relates to a nitride semiconductor device.

### 2. Description of Related Art

High-electron-mobility transistors (HEMTs) that use nitride semiconductors are now being commercialized. When a HEMT is applied to a power device, the HEMT is required to be normally off so that a current path (channel) between the source and drain is open at zero-bias for fail-safe reasons. Japanese Laid-Open Patent Publication No. 2017-73506 discloses a nitride semiconductor HEMT of a normally-off type.

For example, a nitride semiconductor HEMT includes an electron transit layer, which is formed by a gallium nitride (GaN) layer, and an electron supply layer, which is formed by an aluminum gallium nitride (AlGaN) layer. The channel of the HEMT is formed by two-dimensional electron gas (2DEG) generated in the electron transit layer in the vicinity of a heterojunction interface between the electron transit layer and the electron supply layer. Japanese Laid-Open Patent Publication No. 2017-73506 discloses a GaN layer (p-type GaN layer) containing acceptor impurities and arranged under a gate electrode to interrupt the channel formed by 2DEG so that the HEMT will be normally off.

### BRIEF DESCRIPTION OF THE DRAWINGS

FIG. 1 is a schematic cross-sectional view of an exemplary nitride semiconductor device in accordance with a first embodiment.

FIG. 2 is an enlarged cross-sectional view illustrating part of the nitride semiconductor device illustrated in FIG. 1.

FIG. 3 is a schematic plan view of the nitride semiconductor device taken along line F3-F3 in FIG. 1.

FIG. 4 is a plan view enlarging part of FIG. 3 and illustrating the connection structure of a source electrode and a field plate electrode in the nitride semiconductor device.

FIG. 5 is an enlarged cross-sectional view taken along line F5-F5 in FIG. 4 and illustrating part of the nitride semiconductor device.

FIG. 6 is a schematic cross-sectional view of an exemplary nitride semiconductor device in accordance with a second embodiment.

FIG. 7 is a schematic cross-sectional view of an exemplary nitride semiconductor device in accordance with a third embodiment.

FIG. 8 is a schematic cross-sectional view exemplifying a nitride semiconductor device in accordance with a fourth embodiment.

FIG. 9 is a schematic plan view of the nitride semiconductor device illustrating another example of the connection structure of the source electrode and the field plate electrode in the nitride semiconductor device.

FIG. 10 is a schematic plan view of the nitride semiconductor device illustrating a further example of the connection structure of the source electrode and the field plate electrode in the nitride semiconductor device.

### DETAILED DESCRIPTION

Several embodiments of a semiconductor device in accordance with the present disclosure will now be described with reference to the accompanying drawings. In the drawings, elements are illustrated for simplicity and clarity and have not necessarily been drawn to scale. To facilitate understanding, hatching lines may not be shown in the cross-sectional drawings. The accompanying drawings illustrate exemplary embodiments in accordance with the present disclosure and are not intended to limit the present disclosure.

This detailed description includes exemplary embodiments of methods, apparatuses, and/or systems in accordance with the present disclosure. This detailed description is illustrative and is not intended to limit embodiments of the present disclosure or the application and use of the embodiments.

### First Embodiment

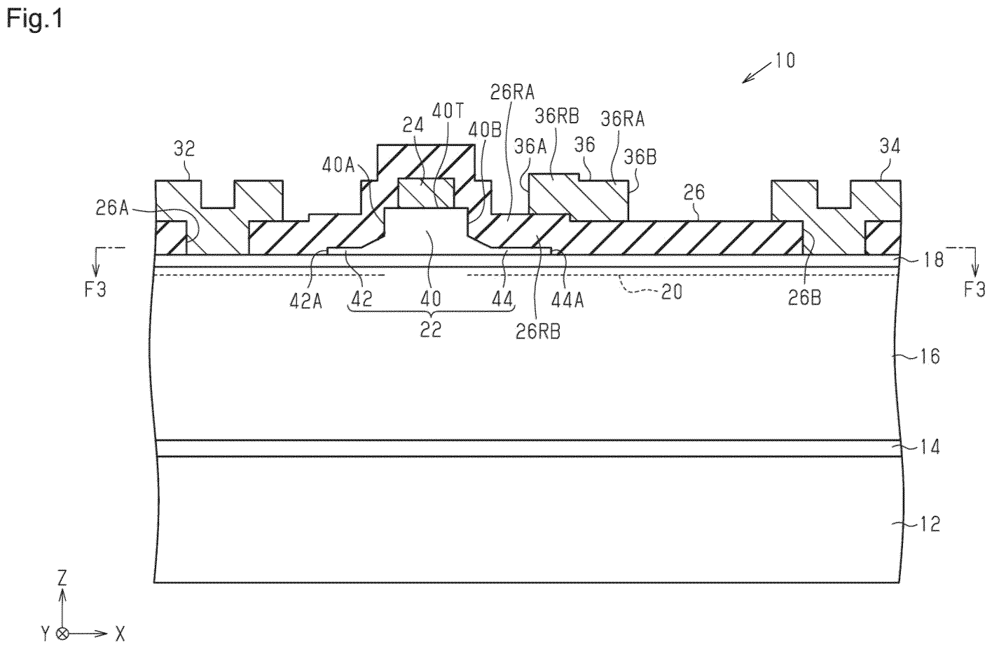

FIG. 1 is a schematic cross-sectional view of an exemplary nitride semiconductor device 10 in accordance with a first embodiment. The overall structure of the nitride semiconductor device 10 will first be described with reference to FIG. 1.

### Overall Structure of Nitride Semiconductor Device

The nitride semiconductor device 10 may be, for example, a high-electron-mobility transistor (HEMT) that uses a nitride semiconductor such as gallium nitride (GaN). The nitride semiconductor device 10 includes a substrate 12, a buffer layer 14 formed on the substrate 12, an electron transit layer 16 formed on the buffer layer 14, and an electron supply layer 18 formed on the electron transit layer 16.

The semiconductor substrate 12 may be formed from silicon (Si), silicon carbide (SiC), GaN, sapphire, or another substrate material. For example, the semiconductor substrate 12 may be a conductive Si substrate. The semiconductor substrate 12 may have a thickness of, for example, 200 μm or greater and 1500 μm or less. The drawings (e.g., FIG. 1) show the XYZ axes that are orthogonal to one another. The Z-axis direction is orthogonal to the main surface of the semiconductor substrate 12. Unless otherwise indicated, the term “plan view” as used in this specification will refer to a view of the nitride semiconductor device 10 taken from above in the Z-axis direction.

The buffer layer 14, which is located between the substrate 12 and the electron transit layer 16, may be formed from any material that reduces lattice mismatching between the substrate 12 and the electron transit layer 16. The buffer layer 14 may include, for example, one or more nitride semiconductor layers. For example, the buffer layer 14 may include at least one of an aluminum nitride (AlN) layer, an aluminum gallium nitride (AlGaN) layer, and a graded AlGaN layer having different aluminum (Al) compositions. For example, the buffer layer 14 may include a single AlN layer, a single AlGaN layer, a layer having an AlGaN/GaN superlattice structure, a layer having an AlN/AlGaN superlattice structure, or a layer having an AlN/GaN superlattice structure.

In one example, the buffer layer 14 includes a first buffer layer that is formed on the substrate 12 and a second buffer layer that is formed on the first buffer layer. The first buffer layer is, for example, an AlN layer and may have a thickness of, for example, approximately 200 nm. The second buffer layer includes, for example, multiple AlGaN layers, and each AlGaN layer may have a thickness of, for example, approximately 100 nm. To reduce leakage current in the buffer layer 14, part of the buffer layer 14 may be doped with impurities to be semi-insulating. In this case, the impurities may be carbon (C) or iron (Fe), and the concentration of the impurities may be, for example, 4×10¹⁶ cm³ or greater.

The electron transit layer 16 is composed of a nitride semiconductor and may be, for example, a GaN layer. The electron transit layer 16 may have a thickness of, for example, 0.5 μm or greater and 2 μm or less. To reduce leakage current in the electron transit layer 16, part of the electron transit layer 16 may be doped with impurities so that regions other than the outermost part of the electron transit layer 16 are semi-insulating. In this case, the impurities are, for example, carbon (C). The concentration of the impurities may be, for example, greater than or equal to 1×10¹⁹ cm⁻³ at a peak concentration.

The electron supply layer 18 is composed of a nitride semiconductor having a larger band gap than the electron transit layer 16 and may be, for example an AlGaN layer. In an AlGaN layer, the band gap will become larger as the Al composition increases. Thus, the electron supply layer 18, which is an AlGaN layer, will have a larger band gap than the electron transit layer 16, which is a GaN layer. For example, the electron supply layer 18 may be formed from AlₓGa₁₋ₓN, where x is 0.1<x<0.4 is satisfied, and, further preferably, 0.2<x<0.3 is satisfied, although there is no limitation to such a range. For example, x may be 0.1<x<0.3. The electron supply layer 18 may have a thickness of, for example, 5 nm or greater and 20 nm or less.

The electron transit layer 16 and the electron supply layer 18 may be composed of nitride semiconductors having different lattice constants. Thus, the nitride semiconductor (e.g., GaN) of the electron transit layer 16 and the nitride semiconductor (e.g., AlGaN) of the electron supply layer 18 form a lattice-mismatched junction. The spontaneous polarization of the electron transit layer 16 and the electron supply layer 18 and the piezoelectric polarization resulting from the stress received by the heterojunction of the electron supply layer 18 cause the energy level of the conduction band of the electron transit layer 16 to be lower than the Fermi level in the proximity of the heterojunction interface between the electron transit layer 16 and the electron supply layer 18. Thus, a two-dimensional electron gas (2DEG) 20 spreads in the electron transit layer 16 at a position proximate to the heterojunction interface of the electron transit layer 16 and the electron supply layer 18 (e.g., distanced by approximately a few nanometers from interface).

The nitride semiconductor device 10 further includes a gate layer 22 formed on the electron supply layer 18, a gate electrode 24 formed on the gate layer 22, and a passivation layer 26 that covers the electron supply layer 18, the gate layer 22, and the gate electrode 24.

The gate layer 22 is composed of a nitride semiconductor containing acceptor impurities and formed on part of the electron supply layer 18. The gate layer 22 may be formed from any material having a smaller band gap than the electron supply layer 18. For example, when the electron supply layer 18 is an AlGaN layer, the gate layer 22 may be a GaN layer doped with acceptor impurities, that is, a p-type GaN layer. The acceptor impurities may contain, for example, at least one of zinc (Zn), magnesium (Mg), and carbon (C). The maximum concentration of the acceptor impurities is, for example, 7×10¹⁸ cm⁻³ or greater and 1×10²⁰ cm⁻³ or less.

The gate electrode 24 is formed on part of the upper surface of the gate layer 22 or on all of the upper surface of the gate layer 22. Further, the gate electrode 24 forms a Schottky junction with the gate layer 22. The gate electrode 24, which includes one or more metal layers, may be, for example, a titanium nitride (TiN) layer. Alternatively, the gate electrode 24 may include a first metal layer (e.g., Ti layer) and a second metal layer (e.g., TiN layer) arranged on the first metal layer. The gate electrode 24 may have a thickness of, for example, 50 nm or greater and 300 nm or less.

The passivation layer 26 is formed by, for example, a single film that is any one of a silicon nitride (SiN) film, a silicon dioxide (SiO₂) film, a silicon oxynitride (SiON) film, an alumina (Al₂O₃) film, an AlN film, and an aluminum oxynitride (AlON) film or a composite film that is a combination of two or more of these films. The passivation layer 26 includes a first opening 26A and a second opening 26B. The gate layer 22 is located between the first opening 26A and the second opening 26B.

The nitride semiconductor device 10 further includes a source electrode 32, which contacts the electron supply layer 18 through the first opening 26A of the passivation layer 26, and a drain electrode 34, which contacts the electron supply layer 18 through the second opening 26B of the passivation layer 26. The nitride semiconductor device 10 further includes a field plate electrode 36 formed on the passivation layer 26.

The source electrode 32, the drain electrode 34, and the field plate electrode 36 are formed by, for example, one or more metal layers including at least one of a Ti layer, a TiN layer, an Al layer, an AlSiCu layer, and an AlCu layer. For example, the source electrode 32, the drain electrode 34, and the field plate electrode 36 may be formed from the same material. This is advantageous since the source electrode 32, the drain electrode 34, and the field plate electrode 36 may all be formed in the same step.

The first opening 26A of the passivation layer 26 is filled with at least part of the source electrode 32. and the second opening 26B of the passivation layer 26 is filled with at least part of the drain electrode 34. The source electrode 32 and the drain electrode 34 are respectively in ohmic contact with the 2DEG underneath the electron supply layer 18 through the first opening 26A and the second opening 26B.

### Stepped Structure of Gate Layer

An exemplary stepped structure of the gate layer 22 will now be described with reference to FIG. 1.

The gate layer 22 includes a ridge 40 where the gate electrode 24 is located, a source-side extension 42 extending from the ridge 40 toward the first opening 26A of the passivation layer 26, and a drain-side extension 44 extending from the ridge 40 toward the second opening 26B of the passivation layer 26. In this manner, the gate layer 22 has a stepped structure formed by the ridge 40 and the extensions 42 and 44.

The ridge 40 is a relatively thick part of the gate layer 22. The ridge 40 includes an upper surface 40T where the gate electrode 24 is located, a first ridge end 40A, that is continuous with the upper surface 40T, and a second ridge end 40B that is continuous with the upper surface 40T. The source-side extension 42 extends from the first ridge end 40A, and the drain-side extension 44 extends from the second ridge end 40B. The ridge 40 may have a rectangular or substantially rectangular (trapezoidal) cross section extending along an XZ plane in FIG. 1. The ridge 40 may have a thickness of, for example, 80 nm or greater and 150 nm or less. The thickness of the ridge 40 refers to the distance from the upper surface 40T of the ridge 40 to the lower surface (lower surface of gate layer 22 contacting electron supply layer 18). The thickness of the gate layer 22 may be determined in accordance with various types of parameters such as the gate breakdown voltage.

The source-side extension 42 extends from the first ridge end 40A toward the first opening 26A, and the drain-side extension 44 extends from the second ridge end 40B toward the second opening 26B. The source-side extension 42 includes an end 42A facing the first opening 26A, and the drain-side extension 44 includes an end 44A facing the second opening 26B. The end 42A of the source-side extension 42 is separated from the first opening 26A, and the end 44A of the drain-side extension 44 is separated from the second opening 26B.

In the example of FIG. 1, the drain-side extension 44 extends outward from the ridge 40 over a greater length than the source-side extension 42 in plan view. The source-side extension 42 and the drain-side extension 44 may, however, have the same length. In the direction extending from the first ridge end 40A toward the first opening 26A, the source-side extension 42 may have a length (length from first ridge end 40A to end 42A of source-side extension 42) of, for example, 0.2 μm or greater and 0.3 μm or less. In the direction extending from the second ridge end 40B toward the second opening 26B, the drain-side extension 44 may have a length (length from second ridge end 40B to end 44A of drain-side extension 44) of, for example, 0.2 μm or greater and 0.6 μm or less.

Further, in the example of FIG. 1, the source-side extension 42 and the drain-side extension 44 each include a sloped portion, which is adjacent to the ridge 40, and a flat portion, which is located in a region separated from the ridge 40 by a predetermined distance (i.e., beyond sloped portion). However, at least one of the source-side extension 42 and the drain-side extension 44 may include only the flat portion or only the sloped portion. The flat portion has a substantially constant thickness. In this specification, a thickness that is “substantially constant” refers to a thickness within a manufacturing tolerance range (for example, 20%). The source-side extension 42 and the drain-side extension 44 may each have a thickness of, for example, 5 nm or greater and 25 nm or less. Further, the flat portion of the source-side extension 42 and the flat portion of the drain-side extension 44 may each have a thickness of, for example 5 nm or greater and 25 nm or less.

### Outline of Field Plate Electrode

The outline of the field plate electrode 36 will now be described with reference to FIG. 1.

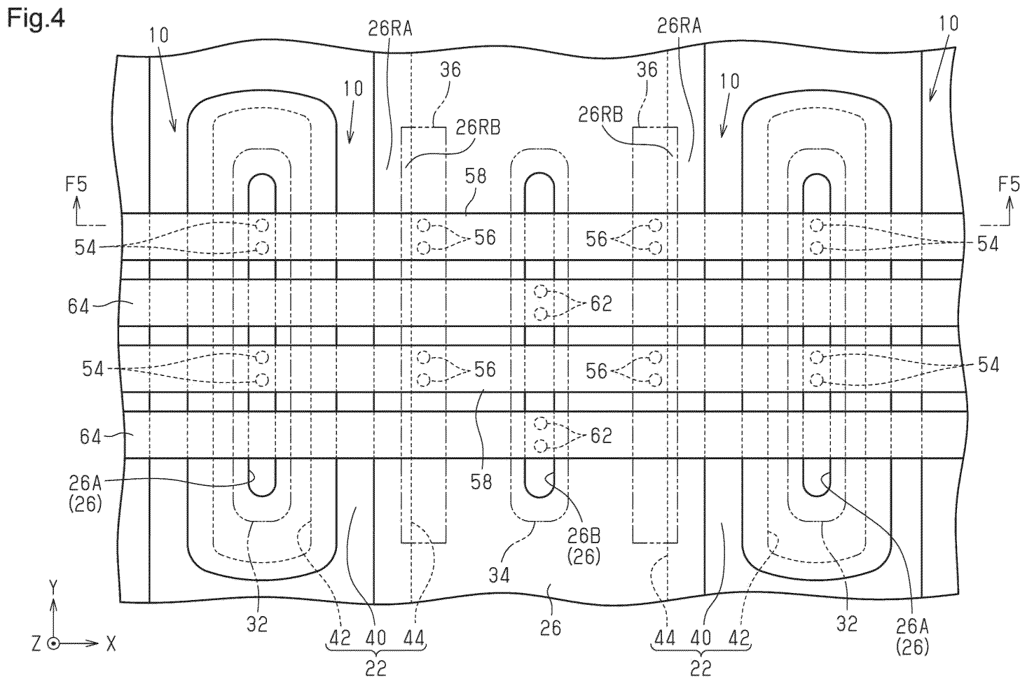

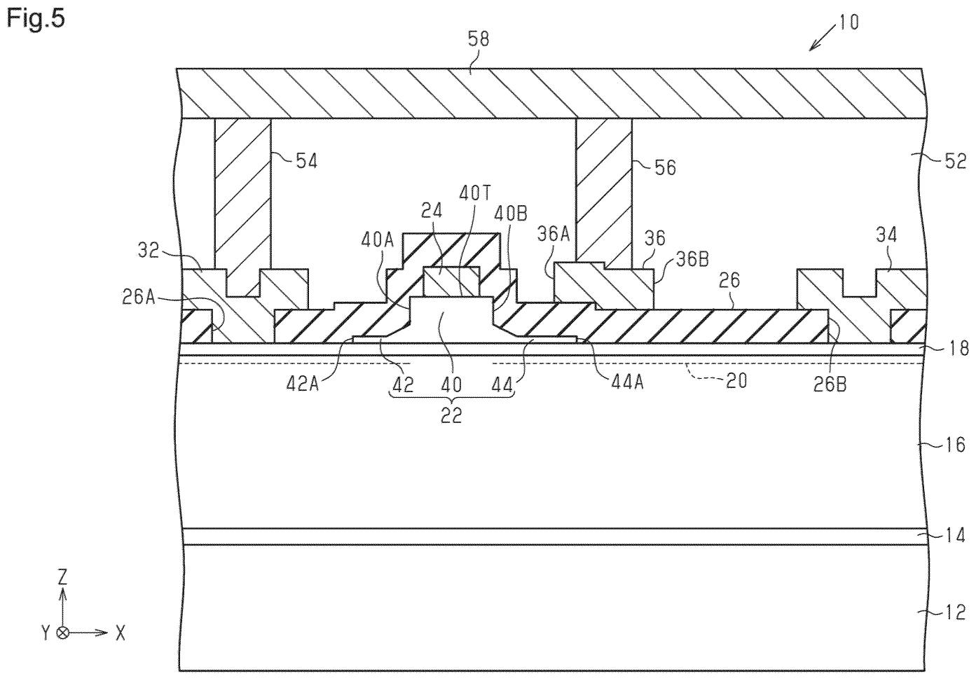

The field plate electrode 36 is formed on the passivation layer 26 between the gate layer 22 and the drain electrode 34. Although not illustrated in FIG. 1, the field plate electrode 36 is electrically connected to the source electrode 32. The structure connecting the field plate electrode 36 and the source electrode 32 will be described later with reference to FIGS. 4 and 5.

The field plate electrode 36 includes a first electrode end 36A and a second electrode end 36B at the opposite side. The first electrode end 36A is the end closer to the source electrode 32 (i.e., end closer to first ridge end 40A), and the second electrode end 36B is the end closer to the drain electrode 34. The first electrode end 36A is separated physically from the source electrode 32, and the second electrode end 36B is separated physically from the drain electrode 34. The second electrode end 36B faces the drain electrode 34.

The field plate electrode 36 may have a length that is greater than the length of the drain-side extension 44 in the direction in which the drain-side extension 44 extends from the ridge 40 toward the second opening 26B (X-direction in FIG. 1, hereafter referred to as extending direction X of drain-side extension 44). The length of the field plate electrode 36 is the length from the first electrode end 36A to the second electrode end 36B of the field plate electrode 36. The field plate electrode 36, however, may have the same length as the drain-side extension 44. The field plate electrode 36 may have a length of, for example, 0.5 μm or greater and 2 μm or less in the extending direction X.

The field plate electrode 36 is arranged on the passivation layer 26 at a position that does not overlap all of the gate layer 22 in plan view or a position that overlaps part of the drain-side extension 44 of the gate layer 22 in plan view. In the example illustrated in FIG. 1, the field plate electrode 36 slightly overlaps the distal portion of the drain-side extension 44 in plan view. The field plate electrode 36 does not overlap all of the drain-side extension 44 in plan view, and does not overlap the ridge 40 and the source-side extension 42 in plan view.

### Positional Relationship of Gate Layer, Field Plate Electrode, and Passivation Layer

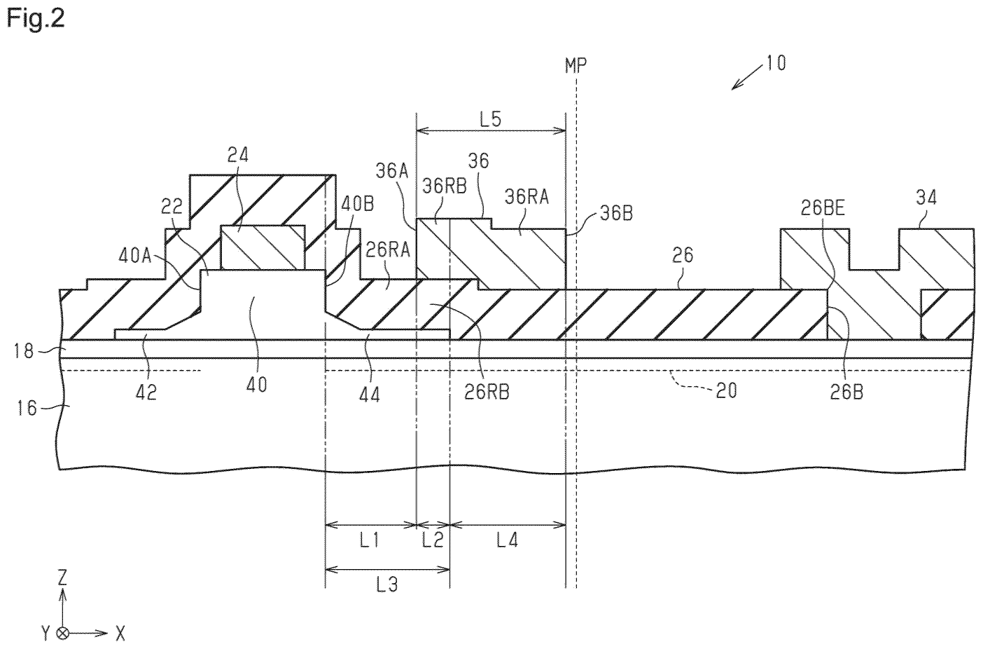

The positional relationship of the field plate electrode 36 and the passivation layer 26 on the drain-side extension 44 of the gate layer 22 will now be described with reference to FIG. 2 focusing on the passivation layer 26.

FIG. 2 is an enlarged cross-sectional view illustrating part of the nitride semiconductor device 10 illustrated in FIG. 1.

As described above, the field plate electrode 36 is arranged on the passivation layer 26 at a position that does not overlap all of the gate layer 22 in plan view or a position that overlaps part of the drain-side extension 44 in plan view. Thus, the passivation layer 26 includes a field plate non-overlapping region 26RA that does not overlap the field plate electrode 36 and is located immediately above the drain-side extension 44.

In the example of FIG. 2 (FIG. 1), the field plate electrode 36 overlaps the end 44A (part including end 44A) of the drain-side extension 44. Thus, in addition to the field plate non-overlapping region 26RA, the passivation layer 26 includes a field plate overlapping region 26RB that overlaps the field plate electrode 36 and is located immediately above the drain-side extension 44. That is, the passivation layer 26 includes the field plate non-overlapping region 26RA (hereafter, simply referred to as “the non-overlapping region 26RA”) and the field plate overlapping region 26RB (hereafter, simply referred to as “the overlapping region 26RB”) that are located immediately above the drain-side extension 44. The non-overlapping region 26RA has a greater area than the overlapping region 26RB.

In the extending direction X of the drain-side extension 44, for example, the non-overlapping region 26RA may have length L1, and the overlapping region 26RB may have length L2. Length L2 is less than length L1. Further, the total of length L1 and length L2 corresponds to length L3 of the drain-side extension 44 in the extending direction X. The non-overlapping region 26RA may include both the sloped portion and the flat portion of the drain-side extension 44. Alternatively, the non-overlapping region 26RA may include only the sloped portion or only the flat portion. In the same manner, the overlapping region 26RB may include both the sloped portion and the flat portion of the drain-side extension 44. Alternatively, the overlapping region 26RB may include only the sloped portion or the flat portion.

Although part of the source electrode 32 (refer to FIG. 1) may be arranged on the passivation layer 26, the field plate electrode 36 and the source electrode 32 are both not arranged on the non-overlapping region 26RA of the passivation layer 26. Thus, the source electrode 32 is arranged on the passivation layer 26 outside the non-overlapping region 26RA.

### Longitudinal Relationship Between Drain-Side Extension of Gate Layer and Field Plate Electrode

The longitudinal relationship between the drain-side extension 44 of the gate layer 22 and the field plate electrode 36 will now be described with reference to FIG. 2.

In the example of FIG. 2 (FIG. 1), the field plate electrode 36 includes a first part 36RA, which does not overlap the drain-side extension 44 in plan view, and a second part 36RB, which overlaps the drain-side extension 44 in plan view. In the extending direction X of the drain-side extension 44, the first part 36RA has length L4, and the second part 36RB has length L2. Length L2 of the overlapping region 26RB of the passivation layer 26 corresponds to length L2 of the second part 36RB of the field plate electrode 36 that overlaps the drain-side extension 44. Length L4 is greater than length L2, and the total of length L4 and length L2 corresponds to length L5 of the field plate electrode 36 in the extending direction X.

As described above, length L5 of the field plate electrode 36 is greater than length L3 of the drain-side extension 44. Further, as described above, length L5 of the field plate electrode 36 is, for example, 0.5 μm or greater and 2 μm or less, and length L3 of the drain-side extension 44 is, for example, 0.2 μm or greater and 0.6 μm or less. For example, length L5 of the field plate electrode 36 may be 1.5 times or greater than length L3 of the drain-side extension 44. Further, length L4 of the first part 36RA of the field plate electrode 36 that does not overlap the drain-side extension 44 may be, for example, 0.4 μm or greater and 2 μm or less. For example, length L4 of the first part 36RA of the field plate electrode 36 may be greater than or equal to length L3 of the drain-side extension 44.

### Position of Field Plate Electrode Between Gate Layer and Drain Electrode

The position of the field plate electrode 36 between the gate layer 22 and the drain electrode 34 will now be described with reference to FIG. 2.

As illustrated in FIG. 2, the field plate electrode 36 between the gate layer 22 and the drain electrode 34 is located closer to the gate layer 22. For example, the second electrode end 36B of the field plate electrode 36 is located closer to the second ridge end 40B than a middle position MP between the second ridge end 40B of the ridge 40 and an opening end 26BE of the second opening 26B that is located closer to the field plate electrode 36.

For example, in the nitride semiconductor device 10, high voltage (e.g., of about 150 V) such as a surge may be momentarily applied to the drain electrode 34. In this state, when the field plate electrode 36 is located in the vicinity of the drain electrode 34, high voltage may also be applied to the passivation layer 26 and the electron supply layer 18 that are located immediately below the field plate electrode 36. This may cause insulation breakdown of the passivation layer 26 and the electron supply layer 18. In this respect, the second electrode end 36B of the field plate electrode 36 is located closer to the gate layer 22 (second ridge end 40B) than the middle position MP so that the field plate electrode 36 is separated farther from the drain electrode 34.

### Layout of Nitride Semiconductor Device

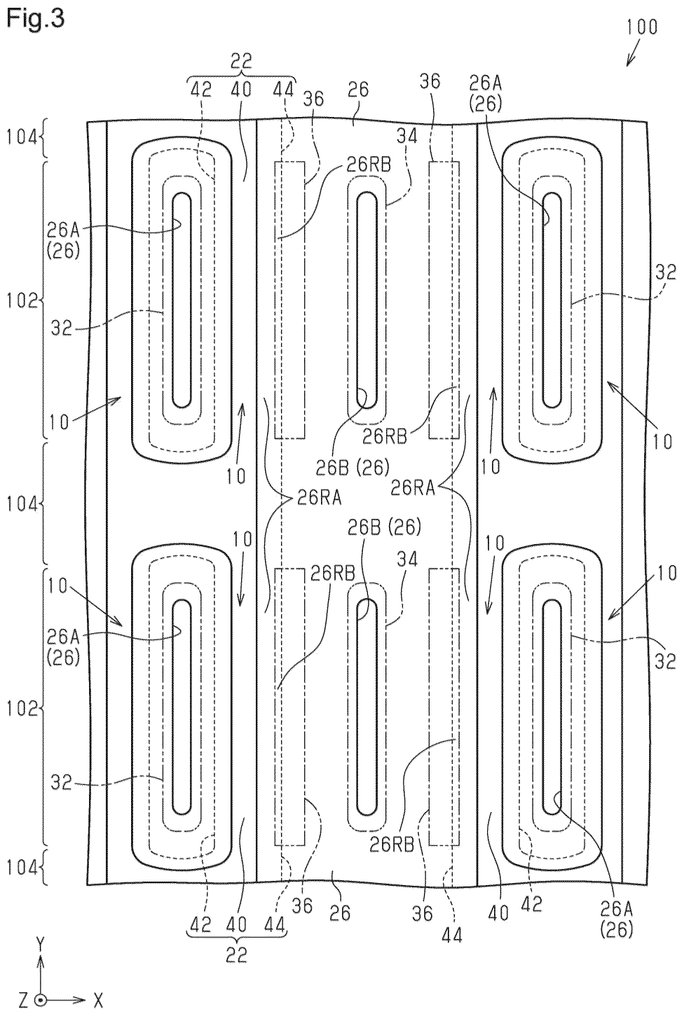

FIG. 3 is a schematic plan view illustrating an exemplary formation pattern 100 of the nitride semiconductor device 10 illustrated in FIG. 1 taken along line F3-F3 in FIG. 1. To facilitate understanding, hatching lines indicating cross-sections are not illustrated in the drawing. The gate electrode 24 is not illustrated in FIG. 3.

As illustrated in FIG. 3, the formation pattern 100 includes alternately arranged active regions 102, which contribute to transistor operations, and non-active regions 104, which do not contribute to transistor operations. The nitride semiconductor device 10 is configured as a HEMT including the source electrode 32, the gate layer 22 where the gate electrode 24 (not illustrated in FIG. 3) is arranged, the field plate electrode 36, and the drain electrode 34 that are arranged adjacent to one another in one direction in the active region 102. The HEMT is actuated when predetermined voltage is applied to the gate electrode 24 and current flows between the source and drain in the active regions 102.

In the example of FIG. 3, in each of the active regions 102, multiple (four illustrated in FIG. 3) nitride semiconductor devices 10 are formed continuously in the X-direction. Each nitride semiconductor device 10 illustrated in FIG. 3 corresponds to the nitride semiconductor device 10 illustrated in FIG. 1. Thus, FIG. 1 illustrates one of the nitride semiconductor devices 10 formed in the active regions 102.

As illustrated in FIG. 3, the passivation layer 26 includes the non-overlapping region 26RA that does not overlap the field plate electrode 36 immediately above the drain-side extension 44. The non-overlapping region 26RA is substantially the entire region of the passivation layer 26 that is located immediately above the drain-side extension 44. In the active regions 102, the field plate electrode 36 overlaps the end 44A of the drain-side extension 44 (part including end 44A) but is separated from the source electrode 32 in plan view.

The field plate electrode 36 is elongated in a direction along the gate layer 22 (Y-direction). In the example of FIG. 3, the field plate electrode 36 may be long enough to traverse the corresponding active region 102 in the direction along the gate layer 22. Further, the field plate electrode 36 may be longer than the source electrode 32 (and drain electrode 34) in the direction along the gate layer 22.

### Connection Structure of Source Electrode and Field Plate Electrode

A connection structure of the source electrode 32 and the field plate electrode 36 will now be described with reference to FIGS. 4 and 5.

FIG. 4 is a plan view enlarging part of FIG. 3 and illustrating the electrical connection structure of the source electrode 32 and the field plate electrode 36. FIG. 5 is an enlarged cross-sectional view taken along line F5-F5 in FIG. 4 and illustrating part of the nitride semiconductor device 10. FIG. 5 illustrates one of the nitride semiconductor devices 10.

As illustrated in FIGS. 4 and 5, the nitride semiconductor device 10 includes an inter-layer insulation layer 52 (not illustrated in FIG. 4), first vias 54, second vias 56, and source wiring lines 58. Each of the first vias 54 and the second vias 56 is a conductor, or wiring. The inter-layer insulation layer 52 covers the source electrode 32, the drain electrode 34, the field plate electrode 36, and the passivation layer 26.

The first vias 54 extend through the inter-layer insulation layer 52 and connect to the source electrode 32. The second vias 56 extend through the inter-layer insulation layer 52 and connect to the field plate electrode 36. The source wiring lines 58 are formed on the inter-layer insulation layer 52 and connected to the first vias 54 and the second vias 56. Thus, the field plate electrode 36 is electrically connected to the source electrode 32 by the second vias 56, the source wiring lines 58, and the first vias 54.

Although not illustrated in cross section, as illustrated in FIG. 4, the nitride semiconductor device 10 further includes third vias 62, which extend through the inter-layer insulation layer 52 and connect to the drain electrode 34, and drain wiring lines 64, which is formed on the inter-layer insulation layer 52 and connected to the third vias 62. Thus, drain voltage is applied to the drain electrode 34 through the drain wiring lines 64 and the third vias 62.

### Operation of Nitride Semiconductor Device

The operation of the nitride semiconductor device 10 will now be described.

The nitride semiconductor device 10 includes the gate layer 22 serving as a nitride semiconductor layer (e.g., p-type GaN layer) containing acceptor impurities. The gate layer 22 includes the ridge 40, the source-side extension 42, and the drain-side extension 44. The source-side extension 42 and the drain-side extension 44 extend from the ridge 40 in opposite directions. The source-side extension 42 and the drain-side extension 44 disperses the lines of electric force concentrated at the lower end of the ridge 40 when a gate positive bias is applied to the extensions 42 and 44 so that the potential at the gate layer 22 becomes uniform in the X-direction. As a result, the electric field intensity is reduced at the end of the gate electrode 24. This reduces gate leakage current during the application of a high gate voltage and allows the gate breakdown voltage to be increased.

Further, the nitride semiconductor device 10 includes the field plate electrode 36 arranged on the passivation layer 26 between the gate layer 22 (gate electrode 24) and the drain electrode 34. When high voltage is applied to the drain electrode 34, the field plate electrode 36 acts to expand the depletion layer from the field plate electrode 36 toward a 2DEG 20, which is located immediately below the field plate electrode 36, and mitigate electric field concentration that occurs in the drain-source region.

For example, the vicinity of the end of the gate electrode 24 located closer to the drain electrode 34 (e.g., second ridge end 40B, end 44A of drain-side extension 44, etc.) is where electric field is apt to concentrate when high voltage is applied to the drain electrode 34. Expansion of the depletion layer immediately below the field plate electrode 36 effectively mitigates electric field concentration at such location. This avoids insulation breakdown of the electron supply layer 18 and the passivation layer 26 that would be caused by such local electric field concentration, and increases the breakdown voltage between the drain and source.

The nitride semiconductor device 10, which includes the field plate electrode 36, has a parasitic capacitance that forms between the field plate electrode 36 and the 2DEG 20 through the electron supply layer 18 (and part of drain-side extension 44) and the passivation layer 26. The parasitic capacitance increases in accordance with the area of the field plate electrode 36 located in the drain-source region.

In this regard, the field plate electrode 36 overlaps part of the drain-side extension 44 of the gate layer 22 in plan view but does not overlap all of the drain-side extension 44. Accordingly, the passivation layer 26 includes the field plate non-overlapping region 26RA that is located immediately above the drain-side extension 44 and does not overlap the field plate electrode 36 (i.e., located where field plate electrode 36 is not arranged). This structure increases the area of the non-overlapping region 26RA (i.e., decreases area of overlapping region 26RB) and reduces the parasitic capacitance between the drain and source.

The nitride semiconductor device 10 of the first embodiment has the advantages described below.

(1-1) The gate layer 22 includes the ridge 40, the source-side extension 42, and the drain-side extension 44. The source-side extension 42 and the drain-side extension 44 reduce the electric filed intensity at the end of the gate electrode 24 during the application of a high gate voltage. This allows the gate breakdown voltage to be increased.

(1-2) The field plate electrode 36 is arranged on the passivation layer 26 between the gate layer 22 and the drain electrode 34. When high voltage is applied to the drain electrode 34, the field plate electrode 36 acts to expand the depletion layer from the field plate electrode 36 toward the 2DEG 20, which is located immediately below the field plate electrode 36, and mitigate electric field concentration that occurs in the drain-source region. This avoids insulation breakdown of the electron supply layer 18 and the passivation layer 26 that would be caused by such local electric field concentration, and increases the breakdown voltage between the drain and source.

(1-3) The passivation layer 26 includes the field plate non-overlapping region 26RA that does not overlap the field plate electrode 36 and is located immediately above the drain-side extension 44. In this structure, the field plate electrode 36 is not arranged on the non-overlapping region 26RA. Thus, parasitic capacitance is not formed in the non-overlapping region 26RA. This reduces the parasitic capacitance between the drain and source. Further, this structure increases the area of the non-overlapping region 26RA (i.e., decreases the area of overlapping region 26RB) and further reduces the parasitic capacitance between the drain and source.

(1-4) The stepped structure of the gate layer 22 (ridge 40 and extensions 42, 44) and the field plate electrode, which covers all of the gate layer 22 (i.e., all of ridge 40 and all of extensions 42, 44), increases the gate breakdown voltage and the breakdown voltage between the drain and source. In this case, however, the arrangement of the field plate electrode increases the parasitic capacitance between the drain and source. This may impose limitations to the high-speed and high-frequency operations of the HEMT. In this respect, the passivation layer 26 includes the field plate non-overlapping region 26RA that does not overlap the field plate electrode 36 and is located immediately above the drain-side extension 44. Thus, the nitride semiconductor device 10 has a HEMT structure that increases the breakdown voltage between the drain and source and reduces the parasitic capacitance between the drain and source while increasing the gate breakdown voltage.

(1-5) The field plate electrode 36 overlaps the end 44A of the drain-side extension 44 in plan view (but does not overlap all of drain-side extension 44). In this structure, the field plate electrode 36 is arranged immediately above the end 44A of the drain-side extension 44. Thus, an electric field concentrated at the end 44A of the drain-side extension 44 is mitigated by the field plate electrode 36. In this manner, electric field concentration is mitigated at the end 44A of the drain-side extension 44, while the parasitic capacitance is reduced between the drain and source.

(1-6) The field plate electrode 36 is separated from the source electrode 32 in the active regions 102. Further, the source electrode 32 includes a region arranged on the passivation layer 26 at a position that does not overlap the drain-side extension 44 of the gate layer 22 in plan view. In the example of FIG. 1, the source electrode 32 includes a region arranged on the passivation layer 26 at a position that does not overlap the drain-side extension 44 and also does not overlap the ridge 40 and the source-side extension 42. As a result, in FIG. 1, only part of the field plate electrode 36 is arranged on the passivation layer 26 immediately above the drain-side extension 44. This structure effectively reduces the parasitic capacitance between the drain and source.

(1-7) The field plate electrode 36 includes the electrode end 36B facing the drain electrode 34. The electrode end 36B is located closer to the second ridge end 40B than the middle position MP between the second ridge end 40B and the opening end 26BE of the second opening 26B that is located closer to the field plate electrode 36. Thus, the field plate electrode 36 is located farther from the drain electrode 34. Consequently, when high voltage such as surge is applied to the drain electrode 34, the concentration of electric field is mitigated at the passivation layer 26 and the electron supply layer 18 that are located immediately below the field plate electrode 36. This avoids insulation breakdown of the passivation layer 26 and the electron supply layer 18.

(1-8) The field plate electrode 36 may have length L5 that is greater than length L3 of the drain-side extension 44 in the extending direction X of the drain-side extension 44. This structure increases the gate breakdown voltage and reduces the parasitic capacitance between the drain and gate, while increasing the breakdown voltage between the drain and source with the field plate electrode 36 that has a larger area.

(1-9) The field plate electrode 36 includes the first part 36RA that does not overlap the drain-side extension 44 in plan view. The first part 36RA may have length L4 that is greater than or equal to length L3 of the drain-side extension 44 in the extending direction X of the drain-side extension 44. This structure effectively reduces the parasitic capacitance between the drain and gate, while increasing the breakdown voltage between the drain and source.

(1-10) The field plate electrode 36 may be formed from the same material as the source electrode 32 and the drain electrode 34. This structure is advantageous since the source electrode 32, the drain electrode 34, and the field plate electrode 36 may all be formed in the same step.

(1-11) The field plate electrode 36 may be greater in length than the source electrode 32 in the direction along the gate layer 22. This structure allows the breakdown voltage between the drain and source to be increased with the field plate electrode 36 that has a larger area.

### Second Embodiment

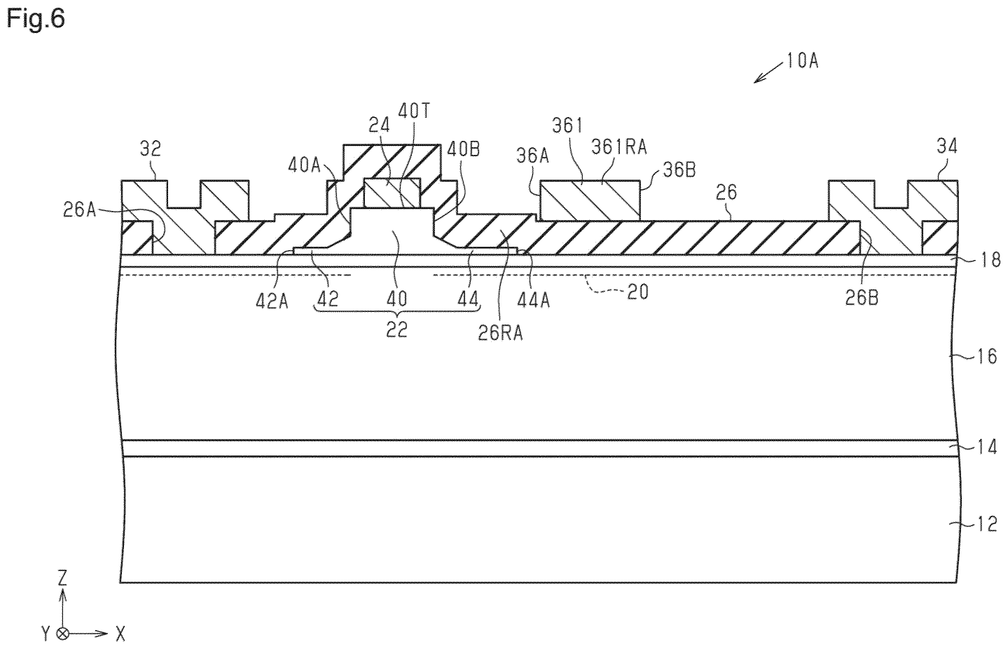

FIG. 6 is a schematic cross-sectional view of an exemplary nitride semiconductor device 10A in accordance with a second embodiment. In FIG. 6, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

As illustrated in FIG. 6, the nitride semiconductor device 10A in accordance with the second embodiment differs from the nitride semiconductor device 10 in accordance with the first embodiment in that the field plate electrode 36 (refer to FIG. 1) of the first embodiment is substituted by a field plate electrode 361. Otherwise, the structure is the same as the first embodiment.

The field plate electrode 361 is arranged on the passivation layer 26 at a position that does not overlap the drain-side extension 44 of the gate layer 22 in plan view. Thus, in the second embodiment, the field plate electrode 361 includes a first part 361RA that is defined by the entire field plate electrode 361. The first part 361RA does not overlap the drain-side extension 44 in plan view. Thus, in the second embodiment, the entirety of the region of the passivation layer 26 located immediately above the drain-side extension 44 in is included in the field plate non-overlapping region 26RA of the passivation layer 26. Except for the point that the field plate electrode 361 does not overlap the drain-side extension 44, the second embodiment may have the same structural characteristics as the first embodiment.

In addition to advantages (1-1) to (1-4) and (1-6) to (1-11) of the first embodiment, the nitride semiconductor device 10A in accordance with the second embodiment has the advantage described below.

(2-1) The field plate electrode 361 does not overlap the drain-side extension 44 in plan view. Thus, the entirety of the region of the passivation layer 26 located immediately above the drain-side extension 44 is included in the field plate non-overlapping region 26RA of the passivation layer 26. In this structure, the region of the drain-side extension 44 does not have parasitic capacitance that would be caused by the field plate electrode 361. This minimizes the parasitic capacitance between the drain and source.

### Third Embodiment

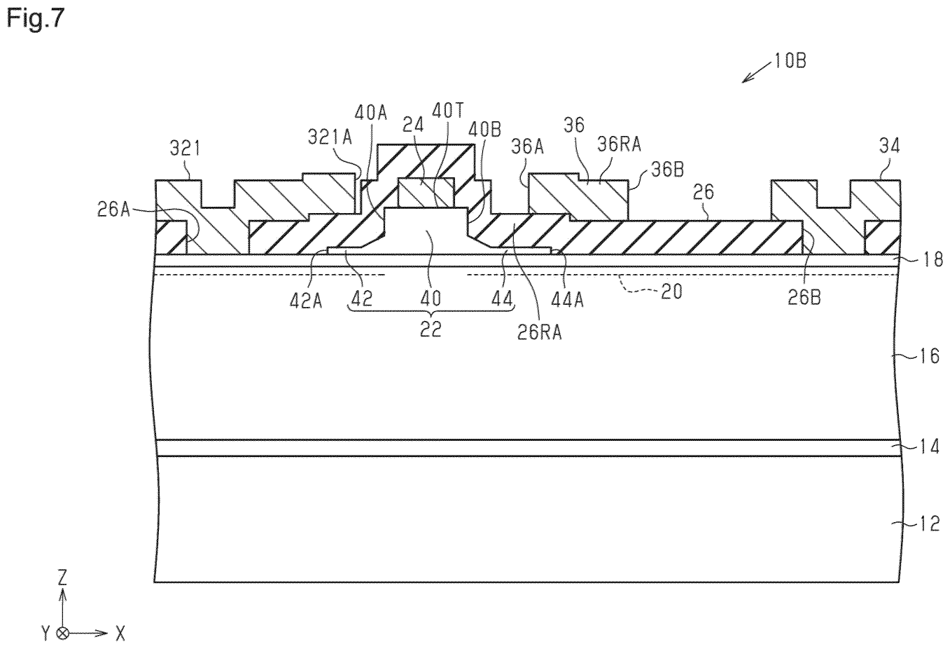

FIG. 7 is a schematic cross-sectional view of an exemplary nitride semiconductor device 10B in accordance with a third embodiment. In FIG. 7, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

As illustrated in FIG. 7, the nitride semiconductor device 10B in accordance with the third embodiment differs from the nitride semiconductor device 10 in accordance with the first embodiment in that the source electrode 32 (refer to FIG. 1) of the first embodiment is substituted by a source electrode 321. Otherwise, the structure is the same as the first embodiment.

The source electrode 321 extends on the passivation layer 26 from the first opening 26A of the passivation layer 26 to a position of the passivation layer 26 overlapping the source-side extension 42 of the gate layer 22 in plan view. In the example of FIG. 7, the source electrode 321 has an end 321A located on the flat part of the source-side extension 42 in plan view although the end 321A may be located on the slope part of the source-side extension 42. In other words, the source electrode 321 may cover part of or all of the source-side extension 42. In any case, the source electrode 321 does not cover the ridge 40 of the gate layer 22. Except for the point that the source electrode 321 overlaps the source-side extension 42, the third embodiment may have the same structural characteristics as the first embodiment.

In addition to advantages (1-1) to (1-5) and (1-7) to (1-11) of the first embodiment, the nitride semiconductor device 10B in accordance with the third embodiment has the advantage described below.

(3-1) The source electrode 321 overlaps the source-side extension 42 in plan view. When the source electrode 321 does not overlap the source-side extension 42, the gate-source parasitic capacitance formed between the source electrode 321 and the 2DEG 20 will decrease. A decrease in the gate-source parasitic capacitance may cause self turn-on. Self turn-on is a phenomenon that turns on the HEMT and occurs when a surge of voltage is applied to the HEMT in an off state causing the gate voltage, which is in accordance with the ratio of the gate-drain parasitic capacitance C_{gd} to the gate-source parasitic capacitance C_{gs}, expressed as C_{gd}/C_{gs}, applied to the gate-source parasitic capacitance C_{gs} to exceed the threshold voltage. The ratio C_{gd}/C_{gs} increases as the gate-source parasitic capacitance C_{gs} decreases.

In this respect, in the third embodiment, the source electrode 321 overlaps the source-side extension 42. This avoids decreases in the gate-source parasitic capacitance C_{gs} and allows self turn-on to be avoided. Further, in the same manner as the first embodiment, in the third embodiment, the passivation layer 26 includes the non-overlapping region 26RA that does not overlap the field plate electrode 36 and is located immediately above the drain-side extension 44. Thus, the gate-drain parasitic capacitance C_{gd} is reduced (as compared with a structure without the non-overlapping region 26RA). This effectively limits increases in the ratio C_{gd}/C_{gs}, and allows self turn-on to be avoided.

### Fourth Embodiment

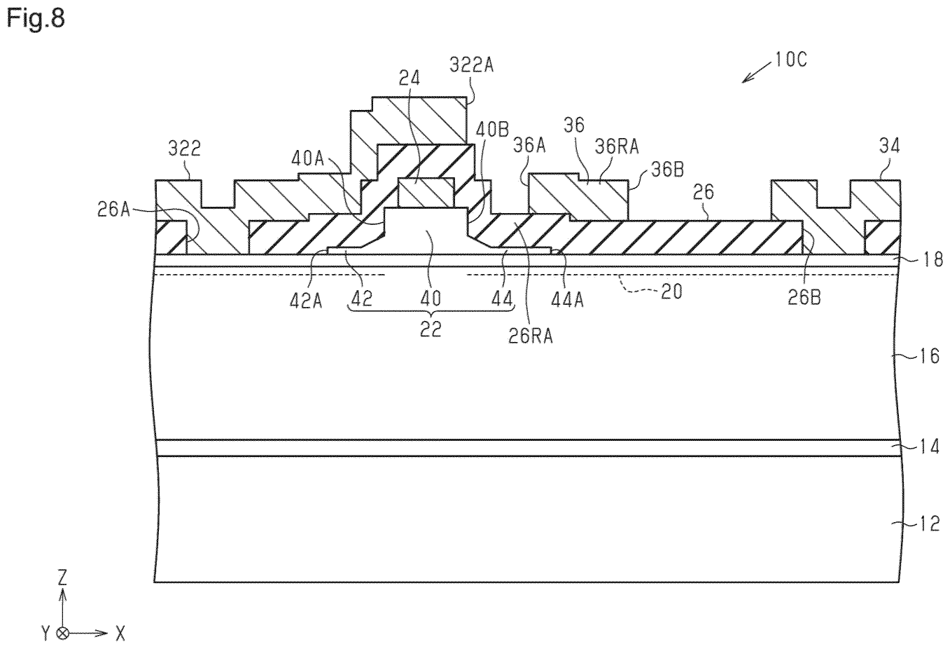

FIG. 8 is a schematic cross-sectional view of an exemplary nitride semiconductor device 10C in accordance with a fourth embodiment. In FIG. 8, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

As illustrated in FIG. 8, the nitride semiconductor device 10C in accordance with the fourth embodiment differs from the nitride semiconductor device 10 in accordance with the first embodiment in that the source electrode 32 (refer to FIG. 1) is substituted by a source electrode 322. Otherwise, the structure is the same as the first embodiment.

The source electrode 322 extends on the passivation layer 26 from the first opening 26A of the passivation layer 26 to a position of the passivation layer 26 overlapping the gate electrode 24 in plan view. In the example of FIG. 8, the source electrode 322 covers all of the gate electrode 24, and the source electrode 322 has an end 322A located on the ridge 40. The source electrode 322 may, however, cover part of the gate electrode 24. Except that the source electrode 322 overlaps the gate electrode 24, the fourth embodiment may have the same structural characteristics as the first embodiment.

In addition to advantages (1-1) to (1-5) and (1-7) to (1-11) of the first embodiment and advantage (3-1) of the third embodiment, the nitride semiconductor device 10C in accordance with the fourth embodiment has the advantage described below.

(4-1) The source electrode 322 overlaps the gate electrode 24 in plan view. Thus, the gate-source parasitic capacitance C_{gs} is reduced more than when using the source electrode 321 of the third embodiment thereby allowing self turn-on to be avoided. This further effectively limits increases in the ratio C_{gd}/C_{gs}, and allows self turn-on to be avoided.

### Modified Examples

The above embodiments may be modified as described below. The above-described embodiments and the modified examples described below may be combined as long as there is no technical contradiction.

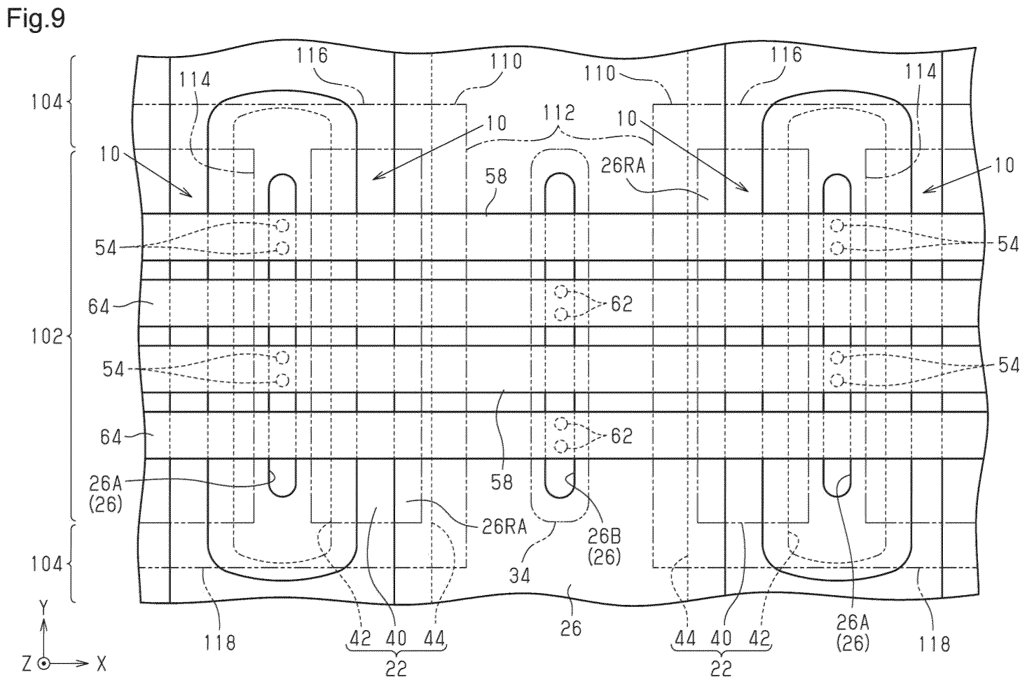

In the first embodiment, the connection structure of the source electrode 32 and the field plate electrode 36 (refer to FIGS. 4 and 5) may be modified as illustrated in FIG. 9. FIG. 9 is a schematic plan view illustrating an example of another connection structure. In addition to the first embodiment, the modified example of FIG. 9 described hereafter may be applied to the second to fourth embodiments.

As illustrated in FIG. 9, the nitride semiconductor device 10 includes a looped electrode 110, and the looped electrode 110 includes a field plate electrode 112, a source electrode 114, and two connection wiring lines 116 and 118. The field plate electrode 112 corresponds to the field plate electrode 36 of the first embodiment, and the source electrode 114 corresponds to the source electrode 32 of the first embodiment. The source electrode 114 and the field plate electrode 112 have the same length in the Y-direction.

The two connection wiring lines 116 and 118 are formed in the same layer as the field plate electrode 112 and the source electrode 114, and connect the field plate electrode 112 and the source electrode 114 in a looped manner. The field plate electrode 112 and the source electrode 114 are arranged within the corresponding active region 102. The connection wiring lines 116 and 118 are arranged within the corresponding non-active region 104. The looped electrode 110 electrically connects the field plate electrode 112 and the source electrode 114 through the connection wiring lines 116 and 118.

The looped electrode 110 such as that illustrated in FIG. 9 may be used when, for example, the field plate electrode 112 has a width (length in X-direction) that is narrow, and the second vias 56 (refer to FIG. 4) are thereby difficult to form in the field plate electrode 112. In this case, the connection wiring lines 116 and 118 are arranged in the non-active regions 104. This reduces the influence of the connection wiring lines 116 and 118 on the element layout and element actions in the active region 102. When using the connection structure of FIG. 9, the advantages of the above embodiments are also obtained.

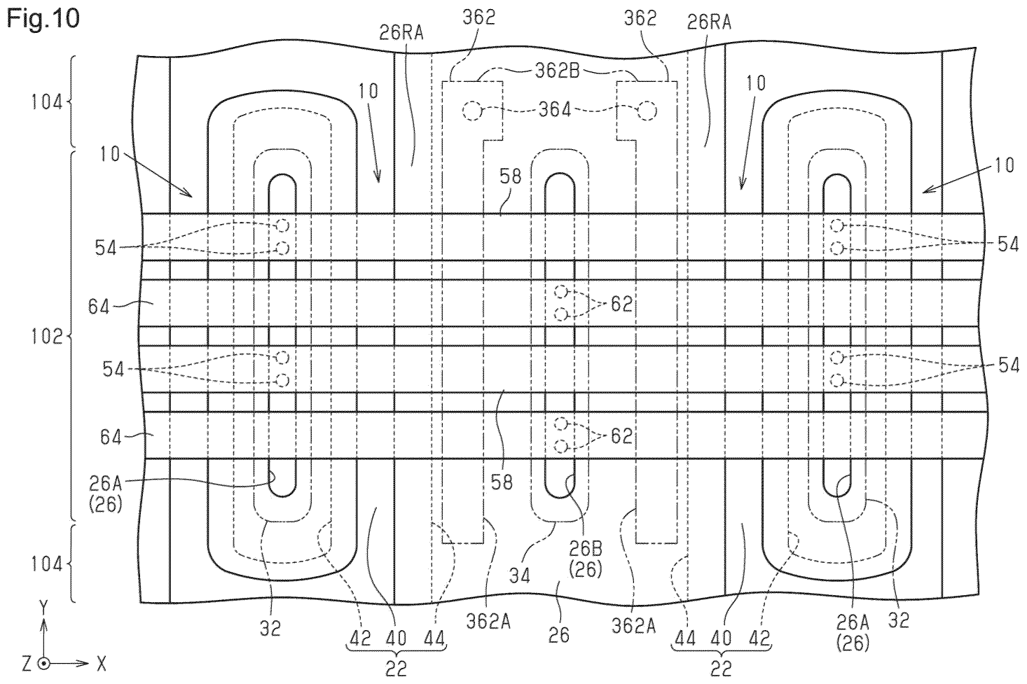

In the first embodiment, the connection structure of the source electrode 32 and the field plate electrode 36 (refer to FIGS. 4 and 5) may be modified as illustrated in FIG. 10. FIG. 10 is a schematic plan view illustrating an example of a further connection structure. In addition to the first embodiment, the modified example of FIG. 10 described hereafter may be applied to the second to fourth embodiments.

As illustrated in FIG. 10, the nitride semiconductor device 10 includes a field plate electrode 362. The field plate electrode 362 is arranged at a position that does not overlap the drain-side extension 44, however, the field plate electrode 362 may be arranged at a position overlapping part of the drain-side extension 44. The field plate electrode 362 is greater in length than the source electrode 32 in the direction along the gate layer 22.

In the example of FIG. 10, the field plate electrode 362 includes an electrode main body 362A and an electrode connection portion 362B. The electrode main body 362A is arranged within the corresponding active region 102. The electrode connection portion 362B is arranged within the corresponding non-active region 104. The electrode connection portion 362B is greater in width (length in X-direction) than the electrode main body 362A. A via 364 extending through the inter-layer insulation layer 52 (refer to FIG. 5) is connected to the electrode connection portion 362B. The via 364 is a conductor, or wiring. Although not illustrated in detail, the electrode main body 362A of the field plate electrode 362 is connected to the source wiring lines 58 by the electrode connection portion 362B, the via 364, and another wiring on the inter-layer insulation layer 52.

For example, when the electrode main body 362A of the field plate electrode 362 has a width (length in X-direction) and the second vias 56 (refer to FIG. 4) are difficult to form in the electrode main body 362A, the field plate electrode 362 of FIG. 10 including the wide electrode connection portion 362B may be used. In the same manner as FIG. 9, the electrode connection portion 362B is arranged within the corresponding non-active region 104. This reduces the influence of the electrode connection portion 362B on the element layout and element actions in the active region 102. When using the connection structure of FIG. 10, the advantages of the above embodiments are also obtained.

In the structure of FIG. 10, the electrode connection portion 362B may be changed in width and shape, and the via 364 may be changed in quantity.

In each of the above embodiments, instead of the structure connecting the field plate electrode 36 to the source electrode 32, the potential at the field plate electrode 36 may be set to a source potential by any potential setting circuit.

In each of the above embodiments, the field plate electrode 36 may be formed from a material differing from that of the source electrode 32 and the drain electrode 34.

In each of the above embodiments, the number of HEMTs formed in each active region 102 is not particularly limited.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is arranged above the second layer without contacting the second layer in another embodiment. Thus, the word “on” will also allow for a structure in which another layer is arranged between the first layer and the second layer. For example, in each of the above embodiments, the electron supply layer 18 is formed on the electron transit layer 16. This means that an intermediate layer may be located between the electron supply layer 18 and the electron transit layer 16 to stably form the 2DEG 20.

The Z-axis direction as referred to in this specification does not necessarily have to be the vertical direction and does not necessarily have to fully coincide with the vertical direction. Accordingly, in the structures disclosed above (e.g., structure illustrated in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

The terms used in this specification to indicate directions such as vertical, horizontal, upward, downward, up, down, forward, rearward, side, left, right, front, and back will be attributed to specific directions of the described and illustrated device. In this specification, a variety of alternative directions may be available for any given direction. Thus, directional terms should not be construed narrowly.

### CLAUSES

Technical concepts that can be understood from each of the above embodiments and modified examples will now be described. The reference characters used to denote elements of the embodiments are illustrated in parenthesis for the corresponding elements of the clauses described below. The reference characters are given as examples to aid understanding and not intended to limit elements to the elements denoted by the reference characters.

### [Clause A1]

A nitride semiconductor device (10; 10A; 10B; 10C), including:
an electron transit layer (16) composed of a nitride semiconductor;
an electron supply layer (18) located on the electron transit layer (16) and composed of a nitride semiconductor having a band gap that is larger than that of the electron transit layer (16);
a gate layer (22) located on part of the electron supply layer (18) and composed of a nitride semiconductor containing acceptor impurities;
a gate electrode (24) located on the gate layer (22);
a passivation layer (26) covering the electron supply layer (18), the gate layer (22), and the gate electrode (24) and including a first opening (26A) and a second opening (26B);
a source electrode (32; 114; 321; 322) contacting the electron supply layer (18) through the first opening (26A);
a drain electrode (34) contacting the electron supply layer (18) through the second opening (26B); and
a field plate electrode (36; 112; 361; 362) located on the passivation layer (26) between the gate layer (22) and the drain electrode (34), where
the gate layer (22) includes
   a ridge (40) where the gate electrode (24) is located,
   a source-side extension (42) extending from the ridge (40) toward the first opening (26A), and
   a drain-side extension (44) extending from the ridge (40) toward the second opening (26B), and
the passivation layer (26) includes a field plate non-overlapping region (26RA) that does not overlap the field plate electrode (36; 112; 361; 362) and is located immediately above the drain-side extension (44).

### [Clause A2]

The nitride semiconductor device (10A) according to clause A1, where the field plate non-overlapping region (26RA) is an entirety of a region of the passivation layer (26) located immediately above the drain-side extension (44).

### [Clause A3]

The nitride semiconductor device (10; 10B; 10C) according to clause A1, where the field plate electrode (36) overlaps an end (44A) of the drain-side extension (44) in plan view.

### [Clause A4]

The nitride semiconductor device (10; 10A; 10B; 10C) according to any one of clauses A1 to A3, where
the source electrode (32), the gate layer (22) where the gate electrode (24) is arranged, the field plate electrode (36), and the drain electrode (34) are arranged adjacent to one another in one direction within an active region (102),
the field plate electrode (36) is separated from the source electrode (32) in the active region (102), and
the source electrode (32) includes a region arranged on the passivation layer (26) at a position that does not overlap the drain-side extension (44) in plan view.

### [Clause A5]

The nitride semiconductor device (10; 10A; 10B; 10C) according to any one of clauses A1 to A4, where the source electrode (32) is arranged on the passivation layer (26) outside the field plate non-overlapping region (26RA).

### [Clause A6]

The nitride semiconductor device (10; 10A; 10B; 10C) according to any one of clauses A1 to A5, where
the ridge (40) includes
   an upper surface (40T) where the gate electrode (24) is located,
   a first ridge end (40A) that is continuous with the upper surface (40T), the source-side extension (42) extending from the first ridge end (40A), and
   a second ridge end (40B) that is continuous with the upper surface (40T), the drain-side extension (44) extending from the second ridge end (40B),
the field plate electrode (36) includes an electrode end (36B) facing the drain electrode (34), and
the electrode end (36B) is located closer to the second ridge end (40B) than a middle position (MP) between the second ridge end (40B) and an opening end (26BE) of the second opening (26B) that is located closer to the field plate electrode (36).

### [Clause A7]

The nitride semiconductor device (10; 10A; 10B; 10C) according to any one of clauses A1 to A6, where the field plate electrode (36) has a length (L5) that is greater than a length (L3) of the drain-side extension (44) in an extending direction (X) in which the drain-side extension (44) extends from the ridge (40) toward the second opening (26B).

### [Clause A8]

The nitride semiconductor device (10; 10A; 10B; 10C) according to clause A7, where
the field plate electrode (36) includes a first part (36RA;361RA) that does not overlap the drain-side extension (44) in plan view, and
the first part (36RA;361RA) of the field plate electrode (36) has a length (L4) that is greater than or equal to the length (L3) of the drain-side extension (44) in the extending direction (X) of the drain-side extension (44).

### [Clause A9]

The nitride semiconductor device (10; 10A; 10B; 10C) according to clause A7, where
the field plate electrode (36) includes a first part (36RA) that does not overlap the drain-side extension (44) in plan view,
the length (L3) of the drain-side extension (44) is greater than or equal to 0.2 μm and less than or equal to 0.6 μm, and
the first part (36RA) of the field plate electrode (36) in the extending direction (X) of the drain-side extension (44) has a length (L4) that is greater than or equal to 0.4 μm and less than or equal to 2 μm.

### [Clause A10]

The nitride semiconductor device (10; 10A; 10B; 10C) according to clause A8 or A9, where
the field plate electrode (36) includes a second part (36RB) that overlaps the drain-side extension (44) in plan view, and
the first part (36RA) of the field plate electrode (36) is longer than the second part (36RB).

### [Clause A11]

The nitride semiconductor device (10; 10A; 10B; 10C) according to any one of clauses A1 to A10, where the field plate electrode (36) is formed from a material that is the same as that of the source electrode (32) and the drain electrode (34).

### [Clause A12]

The nitride semiconductor device (10B) according to any one of clauses A1 to A11, where the source electrode (321) extends on the passivation layer (26) from the first opening (26A) to a position of the passivation layer (26) overlapping the source-side extension (42) in plan view.

### [Clause A13]

The nitride semiconductor device (10C) according to any one of clauses A1 to A12, where the source electrode (322) extends on the passivation layer (26) from the first opening (26A) to a position of the passivation layer (26) overlapping the gate electrode (24) in plan view.

### [Clause A14]

The nitride semiconductor device (10; 10A; 10B; 10C) according to any one of clauses A1 to A13, where the source electrode (32) and the field plate electrode (36) are electrically connected to each other.

### [Clause A15]

The nitride semiconductor device (10; 10A; 10B; 10C) according to clause A14, further including:
an interlayer insulation layer (52) covering the source electrode (32), the drain electrode (34), the field plate electrode (36), and the passivation layer (26);
a first via (54) extending through the interlayer insulation layer (52) and connected to the source electrode (32);
a second via (56) extending through the interlayer insulation layer (52) and connected to the field plate electrode (36); and
a source wiring line (58) formed on the interlayer insulation layer (52) and connected to the first via (54) and the second via (56).

### [Clause A16]

The nitride semiconductor device (10; 10A; 10B; 10C) according to any one of clauses A1 to A15, where
the source electrode (32) and the field plate electrode (36) are elongated in a direction along the gate layer (22) in plan view, and
the field plate electrode (36) is greater in length than the source electrode (32) in the direction along the gate layer (22).

### [Clause A17]

The nitride semiconductor device (10; 10A; 10B; 10C) according to clause A16, where the field plate electrode (362) includes
an electrode main body (362A) extending along the gate layer (22), and
an electrode connection portion (362B) having a width that is greater than that of the electrode main body (362A) in a direction orthogonal to the gate layer (22) in plan view.

### [Clause A18]

The nitride semiconductor device (10; 10A; 10B; 10C) according to clause A14, further including:
a connection wiring line (116; 118) connecting the source electrode (114) and the field plate electrode (112), where
the source electrode (114), the gate layer (22) where the gate electrode (24) is arranged, the field plate electrode (114), and the drain electrode (34) are arranged adjacent to one another in one direction within an active region (102),
the connection wiring line (116; 118) is formed on the passivation layer (26) within a non-active region (104) that is separated from the active region.

### [Clause A19]

The nitride semiconductor device (10; 10A; 10A; 10B; 10) according to clause A18, where
the connection wiring line (116; 118) is one of two connection wiring lines (116; 118) connecting the source electrode (114) and the field plate electrode (112), and
the two connection wiring lines (116, 118), the source electrode (114), and the field plate electrode (112) are connected in a looped manner.

### [Clause A20]

The nitride semiconductor device (10; 10A; 10B; 10C) according to any one of clauses A1 to A19, where
the electron transit layer (16) is a GaN layer,
the electron supply layer (18) is an AlₓGa₁₋ₓN layer (0.1<x<0.3), and
the gate layer (22) is a GaN layer containing the acceptor impurities that include at least one of Mg and Zn.

Exemplary descriptions are given above. In addition to the elements and methods (manufacturing processes) described to illustrate the technology of this disclosure, a person skilled in the art would recognize the potential for a wide variety of combinations and substitutions. All variations within the scope of the claims and their equivalents are included in the disclosure.

1. A nitride semiconductor device, comprising:
an electron transit layer composed of a nitride semiconductor;
an electron supply layer located on the electron transit layer and composed of a nitride semiconductor having a band gap that is larger than that of the electron transit layer;
a gate layer located on part of the electron supply layer and composed of a nitride semiconductor containing acceptor impurities;
a gate electrode located on the gate layer;
a passivation layer covering the electron supply layer, the gate layer, and the gate electrode and including a first opening and a second opening;
a source electrode contacting the electron supply layer through the first opening;
a drain electrode contacting the electron supply layer through the second opening; and
a field plate electrode located on the passivation layer between the gate layer and the drain electrode, wherein
the gate layer includes
a ridge where the gate electrode is located,
a source-side extension extending from the ridge toward the first opening, and
a drain-side extension extending from the ridge toward the second opening, and
the passivation layer includes a field plate non-overlapping region that does not overlap the field plate electrode and is located immediately above the drain-side extension.

2. The nitride semiconductor device according to claim 1, wherein the field plate non-overlapping region is an entirety of a region of the passivation layer located immediately above the drain-side extension.

3. The nitride semiconductor device according to claim 1, wherein the field plate electrode overlaps an end of the drain-side extension in plan view.

4. The nitride semiconductor device according to claim 1, wherein
the source electrode, the gate layer where the gate electrode is arranged, the field plate electrode, and the drain electrode are arranged adjacent to one another in one direction within an active region,
the field plate electrode is separated from the source electrode in the active region, and
the source electrode includes a region arranged on the passivation layer at a position that does not overlap the drain-side extension in plan view.

5. The nitride semiconductor device according to claim 1, wherein the source electrode is arranged on the passivation layer outside the field plate non-overlapping region.

6. The nitride semiconductor device according to claim 1, wherein
the ridge includes
an upper surface where the gate electrode is located,
a first ridge end that is continuous with the upper surface, the source-side extension extending from the first ridge end, and
a second ridge end that is continuous with the upper surface, the drain-side extension extending from the second ridge end, and
the field plate electrode includes an electrode end facing the drain electrode, and
the electrode end is located closer to the second ridge end than a middle position between the second ridge end and an opening end of the second opening that is located closer to the field plate electrode.

7. The nitride semiconductor device according to claim 1, wherein the field plate electrode has a length that is greater than a length of the drain-side extension in an extending direction in which the drain-side extension extends from the ridge toward the second opening.

8. The nitride semiconductor device according to claim 7, wherein
the field plate electrode includes a first part that does not overlap the drain-side extension in plan view, and
the first part of the field plate electrode has a length that is greater than or equal to the length of the drain-side extension in the extending direction of the drain-side extension.

9. The nitride semiconductor device according to claim 7, wherein
the field plate electrode includes a first part that does not overlap the drain-side extension in plan view,
the length of the drain-side extension is greater than or equal to 0.2 μm and less than or equal to 0.6 μm, and
the first part of the field plate electrode in the extending direction of the drain-side extension has a length that is greater than or equal to 0.4 μm and less than or equal to 2 μm.

10. The nitride semiconductor device according to claim 8, wherein
the field plate electrode includes a second part that overlaps the drain-side extension in plan view, and
the first part of the field plate electrode is longer than the second part.

11. The nitride semiconductor device according to claim 1, wherein the field plate electrode is formed from a material that is the same as that of the source electrode and the drain electrode.

12. The nitride semiconductor device according to claim 1, wherein the source electrode extends on the passivation layer from the first opening to a position of the passivation layer overlapping the source-side extension in plan view.

13. The nitride semiconductor device according to claim 1, wherein the source electrode extends on the passivation layer from the first opening to a position of the passivation layer overlapping the gate electrode in plan view.

14. The nitride semiconductor device according to claim 1, wherein the source electrode and the field plate electrode are electrically connected to each other.

15. The nitride semiconductor device according to claim 14, further comprising:
an interlayer insulation layer covering the source electrode, the drain electrode, the field plate electrode, and the passivation layer;
a first via extending through the interlayer insulation layer and connected to the source electrode;
a second via extending through the interlayer insulation layer and connected to the field plate electrode; and
a source wiring line formed on the interlayer insulation layer and connected to the first via and the second via.

16. The nitride semiconductor device according to claim 1, wherein
the source electrode and the field plate electrode are elongated in a direction along the gate layer in plan view, and
the field plate electrode is greater in length than the source electrode in the direction along the gate layer.

17. The nitride semiconductor device according to claim 16, wherein the field plate electrode includes
an electrode main body extending along the gate layer, and
an electrode connection portion having a width that is greater than that of the electrode main body in a direction orthogonal to the gate layer in plan view.

18. The nitride semiconductor device according to claim 14, further comprising:
a connection wiring line connecting the source electrode and the field plate electrode, wherein
the source electrode, the gate layer where the gate electrode is arranged, the field plate electrode, and the drain electrode are arranged adjacent to one another in one direction within an active region, and
the connection wiring line is formed on the passivation layer within a non-active region that is separated from the active region.

19. The nitride semiconductor device according to claim 18, wherein
the connection wiring line is one of two connection wiring lines connecting the source electrode and the field plate electrode, and
the two connection wiring lines, the source electrode, and the field plate electrode are connected in a looped manner.

20. The nitride semiconductor device according to claim 1, wherein
the electron transit layer is a GaN layer,
the electron supply layer is an AlₓGa₁₋ₓN layer, where x is 0.1<x<0.3, and
the gate layer is a GaN layer containing the acceptor impurities that include at least one of Mg and Zn.
